(19) United States
(12) Patent Application Publication
(10) Pub. No.: US 2006/0102284 A1
(43) Pub. Date: May 18, 2006

(54) SEMICONDUCTOR MANUFACTURING EQUIPMENT

(76) Inventors: Hsien-Che Teng, Tai-Nan City (TW); Chin-Fu Lin, Tai-Nan City (TW); Jen-Yuan Wu, Yun-Lin Hsien (TW)

Correspondence Address: NORTH AMERICA INTELLECTUAL PROPERTY CORPORATION, P.O. BOX 506, MERRIFIELD, VA, 22116, US

(21) Appl. No.: 10/904,541

(22) Filed: Nov. 15, 2004

(51) Int. Cl. H01L 21/306

(52) U.S. Cl. 156/345.29; 156/345.32

(57) ABSTRACT

A semiconductor manufacturing equipment comprising a canopy, a semiconductor processing device, a load port, a robot arm or a transferring device, an air vent, and a chemical filter to remove chemical substance in the air. A HEPA or ULPA filter may be included to filter off particulates. The load port may have a standardized mechanical interface (SMIF) suitable for SMIF pods. In the case that the semiconductor processing device is a copper processing tool, an advantage of preventing copper from corrosion is attained in the present invention by removing chemical substance.

### BACKGROUND OF INVENTION

1. Field of the Invention

The present invention relates to a semiconductor manufacturing equipment, particularly a semiconductor manufacturing equipment having a standardized mechanical interface.

2. Description of the Prior Art

Manufacturing environments are becoming strict and well controlled accompanying the development of IC integrity in the semiconductor industry. The wafer size has been developed from 8 to 12 inches. The feature size of 0.18 μm to 0.25 μm has been further developed to the deep sub-micron size of 0.07 μm to 0.11 μm, and thus DRAM capacity has increased from the capacity of 64 MB to 128 MB to the capacity of about 256 MB to 1 GB. Thus, the conditions of the manufacturing environment, such as temperature, humidity, particles, and trace chemical substance, have relatively stringent requirements. For reducing the cost of the manufacturing environment structure, novel structures such as clean rooms are devised, one of which is the design of a mini-environment clean room (MCR) with a standardized mechanical interface. In the clean room or mini-environment clean room, the condition parameters, such as airflow velocity, airflow distribution, pressure, humidity, and contaminant sources are strictly controlled.

For controlling the contaminating particles, an ultra-low penetration air filter (ULPA) or a high-efficiency particulate air filter (HEPA) has been installed at the air entrance of a clean room, MCR, or semiconductor manufacturing equipment. FIG. 1 shows a schematic diagram of a conventional manufacturing equipment 10 having a canopy 12, a semiconductor processing device in the canopy 12, a load port 16 on the wall of the canopy as the entrance of pods 20, a transferring device in section 18 in the canopy 12 for transferring wafers 22 in the pods to the semiconductor processing device, an air vent (not shown) on the wall of the canopy 12 near the load port 16, and a HEPA or ULPA filter 24 covering the air vent. A fan 26 may be installed at the air vent to facilitate air entering the canopy 12. However, both the ULPA and HEPA filter out particles in the air just by physical blocking or adsorption and cannot remove chemical substance in the air. During copper processes for semiconductor devices, exposed copper on wafers tends to be corroded by chemical substance, especially acids and bases, in the air, and thus, the yield is deteriorated.

Therefore, a novel semiconductor manufacturing equipment is still needed in order to remove chemical substance in the air for providing an optimized semiconductor manufacturing environment.

### SUMMARY OF INVENTION

It is therefore an objective of the present invention to provide a semiconductor manufacturing equipment which comprises a chemical filter for removing chemical substance in air entering the equipment.

According to the present invention, a semiconductor manufacturing equipment is provided comprising a canopy, a semiconductor processing device in the canopy, a load port on the wall of the canopy for loading at least one pod, a robot arm in the canopy for transferring wafers in the pod to the semiconductor processing device or wafers in the semiconductor processing device to the pod, an air vent on the wall of the canopy near the load port, a HEPA or ULPA filter covering the air vent for filtering out particulates in air entering the canopy, and a chemical filter installed in a stack with the HEPA or ULPA filter for removing chemical substance in the air entering the canopy.

According to the present invention, another embodiment of the semiconductor manufacturing equipment is provided comprising a canopy, a semiconductor processing device in the canopy, a load port having a standardized mechanical interface (SMIF) on the wall of the canopy for loading at least one SMIF pod, a transferring device in the canopy for transferring wafers in the SMIF pod to the semiconductor processing device or wafers in the semiconductor processing device to the SMIF pod, an air vent on the wall of the canopy near the load port, and a chemical filter located on the wall of the canopy and covering the air vent for removing chemical substance in the air entering the canopy.

The semiconductor manufacturing equipment according to the present invention can remove chemical substance, such as acids or bases, in the air since a chemical filter is used, and thus has an excellent filtering efficiency as compared to a conventional semiconductor manufacturing equipment having only a HEPA or ULPA filter.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram showing a conventional semiconductor manufacturing equipment.

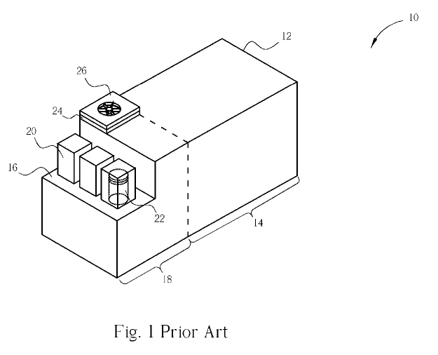

FIG. 2 is a schematic diagram showing a semiconductor manufacturing equipment according to the present invention.

FIG. 3 is a schematic diagram showing another semiconductor manufacturing equipment according to the present invention.

### DETAILED DESCRIPTION

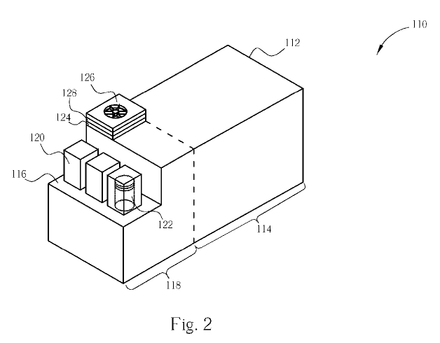

Please refer to FIG. 2 showing a schematic diagram of a semiconductor manufacturing equipment according to the present invention. According to the present invention, the semiconductor manufacturing equipment 110 comprises a canopy 112, a semiconductor processing device (not shown), a load port 116, a robot arm (not shown), an air vent (not shown), a HEPA or ULPA filter 124, and a chemical filter 128. The semiconductor manufacturing equipment 110 may further comprise a fan 126.

The canopy 112 is used for providing a manufacturing environment separated from the outside environment and accommodating a semiconductor processing device (not shown) and a robot arm (not shown) or a transferring device (not shown). Therefore, the canopy 112 may be as big as a mini-environment clean room or as small as a single manufacturing tool. At least an air vent (not shown) and at least a load port 116 are provided on the wall of the canopy 112.

The load port 116 on the wall of the canopy 112, as an entrance and an exit of the semiconductor manufacturing equipment 110, is used for loading a plurality of pods 120 containing wafers for processing. The load port 116 may be provided with a standardized mechanical interface (SMIF) for loading a plurality of standardized SMIF pods for adapting to the technique of mini-environment. Alternatively, the interface environment of the load port may be provided to accommodate to the front opening unified pod (FOUP).

Also as shown in FIG. 2, a robot arm or a transferring device is accommodated in the section 118 in the canopy 112 for transferring wafers 122 in the pod 120 or SMIF pod to the semiconductor processing device for processing or for transferring wafers at the semiconductor processing device to the pod 120 or SMIF pod for the next manufacturing stage.

An air vent is provided on the wall, such as the vertical wall or the top wall (ceiling), of the canopy 112 near the load port 116, for allowing the air to enter the canopy 112. The air vent is covered with a HEPA or ULPA filter 124 as a physical filter to filter out particulates, such as particles having sizes larger than 0.12 μm, in the air entering to the canopy 112. A chemical filter 128 is installed in a stack with the HEPA or ULPA filter for removing chemical substance in the air entering the canopy. The order for the stack is not limited. The chemical substance may be, for example, acids or bases or other corrosive to exposed copper, among these, such as HF, HCl, F₂, Cl₂, NH₄OH, H₃PO₄, HNO₃, H₂SO₄, and NH₃.

The chemical filter 128 comprises chemical material, such as activated charcoal, activated carbon fiber, zeolite, silica gel, ceramic material, a non-woven ion exchange cloth or fiber, ion exchange resin, activated charcoal coated with acid or alkaline substance, activated charcoal on a manganese dioxide carrier, a metallic catalyst, or a photo-sensitive catalyst, to adsorb, neutralize, or react chemical substance in the air to remove the chemical substance.

A fan 126 may be further provided at the air vent to facilitate the entering of air into the canopy 112.

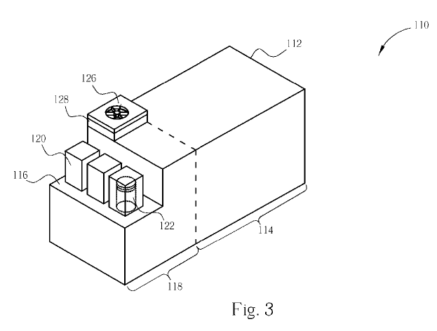

The semiconductor manufacturing equipment according to the present invention is characterized in the chemical filter installed at the air vent near the load port. One aspect of the present invention is a semiconductor manufacturing equipment provided with a chemical filter, as shown in FIG. 3, and another aspect of the present invention is a semiconductor manufacturing equipment provided with both a chemical filter and a physical filter, as shown in FIG. 2, which can be accomplished by installing the chemical filter overlap the existing physical filter of the semiconductor manufacturing equipment. Such equipment can further be provided with a fan.

In the semiconductor manufacturing equipment of the present invention, the semiconductor processing device is located in section 114 to accept wafers transferred by the robot arm or the transferring device for processing. The semiconductor processing device may be, for example, a copper sputtering machine, a copper depositing machine, a chemical mechanical polishing machine, a copper washing machine, or a copper stripping machine. Alternatively, the semiconductor processing device is a machine for use in a copper process in 12-inch wafer manufacturing. In these machines used in manufacturing, copper on wafers may be exposed to ambient air. Therefore, by installing a chemical filter near the load port for loading the pods, the copper-corrosive chemical substance, such as acids and bases, in the air entering the canopy can be removed, according to the present invention.

In a conventional semiconductor manufacturing equipment, only a physical filter is provided for filtering out particulates in the air, while the semiconductor manufacturing equipment of the present invention additionally comprises a chemical filter for filtering chemical substance in the incoming air, and thus the chemical substance harmful to exposed copper on wafers can be removed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor manufacturing equipment, comprising:
a canopy;
a semiconductor processing device in the canopy;
a load port on the wall of the canopy for loading at least one pod;
a robot arm in the canopy for transferring wafers in the pod to the semiconductor processing device or wafers in the semiconductor processing device to the pod;
an air vent on the wall of the canopy near the load port;
a HEPA or ULPA filter covering the air vent for filtering out particulates in air entering the canopy; and
a chemical filter installed in a stack with the HEPA or ULPA filter for removing chemical substance in the air entering the canopy.

2. The equipment of claim 1, wherein the chemical filter comprises chemical material.

3. The equipment of claim 2, wherein the chemical material is activated charcoal, activated carbon fiber, zeolite, silica gel, ceramic material, a non-woven ion exchange cloth or fiber, ion exchange resin, activated charcoal coated with acid or alkaline substance, activated charcoal on a manganese dioxide carrier, a metallic catalyst, or a photo-sensitive catalyst.

4. The equipment of claim 1, wherein the chemical substance in the air is an acid or a base.

5. The equipment of claim 4, wherein the chemical substance in the air is HF, HCl, F₂, Cl₂, NH₄OH, H₃PO₄, HNO₃, H₂SO₄, or NH₃.

6. The equipment of claim 1, further comprising a fan installed at the air vent for facilitating the entering of the air.

7. The equipment of claim 1, wherein the semiconductor processing device is a copper sputtering machine, a copper depositing machine, a chemical mechanical polishing machine, a copper washing machine, or a copper stripping machine.

8. The equipment of claim 1, wherein the semiconductor processing device is a machine for use in a copper process in 12-inch wafer manufacturing.

9. A semiconductor manufacturing equipment, comprising:
a canopy;
a semiconductor processing device in the canopy;
a load port having a standardized mechanical interface (SMIF) on the wall of the canopy for loading at least one SMIF pod;
a transferring device in the canopy for transferring wafers in the SMIF pod to the semiconductor processing device or wafers in the semiconductor processing device to the SMIF pod;
an air vent on the wall of the canopy near the load port; and
a chemical filter located on the wall of the canopy and covering the air vent for removing chemical substance in the air entering the canopy.

10. The equipment of claim 9, further comprising a HEPA or ULPA filter installed in a stack with the chemical filter and covering the air vent.

11. The equipment of claim 10, further comprising a fan installed at the air vent.

12. The equipment of claim 9, wherein the chemical filter comprises chemical material.

13. The equipment of claim 12, wherein the chemical material is activated charcoal, activated carbon fiber, zeolite, silica gel, ceramic material, a non-woven ion exchange cloth or fiber, ion exchange resin, activated charcoal coated with acid or alkaline substance, activated charcoal on a manganese dioxide carrier, a metallic catalyst, or a photo-sensitive catalyst.

14. The equipment of claim 13, wherein the chemical substance in the air is an acid or a base.

15. The equipment of claim 14, wherein the chemical substance in the air is HF, HCl, F₂, Cl₂, NH₄OH, H₃PO₄, HNO₃, H₂SO₄, or NH₃.

16. The equipment of claim 9, wherein the semiconductor processing device is a copper sputtering machine, a copper depositing machine, a chemical mechanical polishing machine, a copper washing machine, or a copper stripping machine.

17. The equipment of claim 9, wherein the semiconductor processing device is a machine for use in a copper process in 12-inch wafer manufacturing.
